(19) United States
(12) Patent Application Publication
(10) Pub. No.: US 2016/0099290 A1
(43) Pub. Date: Apr. 7, 2016

(54) MEMORY DEVICE

(71) Applicant: Kabushiki Kaisha Toshiba, Minato-ku (JP)

(72) Inventor: Yoshiaki ASAO, Yokkaichi (JP)

(73) Assignee: Kabushiki Kaisha Toshiba, Minato-ku (JP)

(21) Appl. No.: 14/637,791

(22) Filed: Mar. 4, 2015

(30) Foreign Application Priority Data
Oct. 3, 2014 (JP) 2014-205296

(51) Int. Cl. H01L 27/24; H01L 45/00

(52) U.S. Cl. CPC H01L 27/2436; H01L 45/1253; H01L 45/1233; H01L 45/06; H01L 45/144

(57) ABSTRACT

According to one embodiment, a memory device includes a first gate electrode, a second gate electrode, a third gate electrode, a first active area and a second active area on a substrate. The first to the third gate electrodes extend in a first direction. The first active area and the second active area extend in a second direction. The first direction and the second direction cross each other. The memory device includes a first contact, a second contact, a third contact, a fourth contact, variable resistance layer, a first interconnection layer, a second interconnection layer and the second interconnection layer. The variable resistance layer and the first interconnection layer extend in the first direction. The second interconnection layer and the third interconnection layer extend in the second direction.

### CROSS-REFERENCE TO RELATED APPLICATIONS

This application is based upon and claims the benefit of priority from Japanese Patent Application No. 2014-205296, filed on Oct. 3, 2014; the entire contents of which are incorporated herein by reference.

### FIELD

Embodiments described herein relate to a memory device.

### BACKGROUND

As a variable resistance memory, various memories such as a super-lattice phase change memory, a phase change memory, and an ion memory have been proposed and developed. The memories respectively adopt different operational principles such as a phase change of a super-lattice, a change of a crystalline state, and filament forming performed through ionic conduction. However, all the memories are in common with one another in that resistance of a memory element thereof is transitional between a high-resistance state and a low-resistance state by being applied with a voltage or a current. In such memory devices, reduction of manufacturing cost is also required.

### BRIEF DESCRIPTION OF THE DRAWINGS

FIG. 1 is a block diagram showing a configuration of a variable resistance memory of a first embodiment;

FIG. 2 is a diagram for describing a configuration and an operation of the memory cell MC of the first embodiment;

FIG. 3 is a layout of the variable resistance memory according to the first embodiment;

FIG. 4A is a cross-sectional view taken along line A-A′ in FIG. 3;

FIG. 4B is a cross-sectional view taken along line B-B′ in FIG. 3;

FIG. 5A is a cross-sectional view taken along line A-A′ in FIG. 3 to illustrate a manufacturing method for the memory device according to the first embodiment;

FIG. 5B is a cross-sectional view taken along line B-B′ in FIG. 3 to illustrate the manufacturing method for the memory device;

FIG. 6A is a cross-sectional view taken along line A-A′ in FIG. 3 to illustrate the manufacturing method for the memory device according to the first embodiment;

FIG. 6B is a cross-sectional view taken along line B-B′ in FIG. 3 to illustrate the manufacturing method for the memory device according to the first embodiment;

FIG. 7 is a cross-sectional view illustrating a manufacturing method for the memory device according to the first embodiment;

FIG. 8A is a cross-sectional view taken along line A-A′ in FIG. 3 to illustrate the manufacturing method for the memory device according to the first embodiment;

FIG. 8B is a cross-sectional view taken along line B-B′ in FIG. 3 to illustrate the manufacturing method for the memory device according to the first embodiment;

FIG. 9A is a cross-sectional view taken along line A-A′ in FIG. 3 to illustrate the manufacturing method for the memory device according to the first embodiment;

FIG. 9B is a cross-sectional view taken along line B-B′ in FIG. 3 to illustrate the manufacturing method for the memory device according to the first embodiment;

FIG. 10A is a cross-sectional view taken along line A-A′ in FIG. 3 to illustrate the manufacturing method for the memory device according to the first embodiment;

FIG. 10B is a cross-sectional view taken along line B-B′ in FIG. 3 to illustrate the manufacturing method for the memory device according to the first embodiment;

FIG. 11A is a cross-sectional view taken along line A-A′ in FIG. 3 to illustrate the manufacturing method for the memory device according to the first embodiment;

FIG. 11B is a cross-sectional view taken along line B-B′ in FIG. 3 to illustrate the manufacturing method for the memory device according to the first embodiment;

FIG. 12 is a cross-sectional view illustrating the manufacturing method for the memory device according to the first embodiment;

FIG. 13A is a cross-sectional view taken along line A-A′ in FIG. 3 to illustrate the manufacturing method for the memory device according to the first embodiment;

FIG. 13B is a cross-sectional view taken along line B-B′ in FIG. 3 to illustrate the manufacturing method for the memory device according to the first embodiment;

FIG. 14 is a layout of the variable resistance memory according to a variation of the first embodiment;

FIG. 15 is a cross-sectional view taken along line A-A′ in FIG. 14;

FIG. 16A is a layout of the variable resistance memory according to the second embodiment;

FIG. 16B is a layout of the variable resistance memory according to the second embodiment;

FIG. 17A is a cross-sectional view taken along line A-A′ in FIG. 16A to illustrate a manufacturing method for the memory device according to the second embodiment;

FIG. 17B is a cross-sectional view taken along line B-B′ in FIG. 16A to illustrate a manufacturing method for the memory device according to the second embodiment;

FIG. 17C is a cross-sectional view taken along line C-C′ in FIG. 16A to illustrate a manufacturing method for the memory device according to the second embodiment;

FIG. 18 is a layout of the variable resistance memory according to a third embodiment;

FIG. 19A is a cross-sectional view taken along line A-A′ in FIG. 18 to illustrate a manufacturing method for the memory device according to the third embodiment;

FIG. 19B is a cross-sectional view taken along line B-B′ in FIG. 18 to illustrate a manufacturing method for the memory device according to the third embodiment;

FIG. 19C is a cross-sectional view taken along line C-C′ in FIG. 18 to illustrate a manufacturing method for the memory device according to the third embodiment;

FIG. 20 is a layout of the variable resistance memory according to the fourth embodiment;

FIG. 21 is a diagram for describing a configuration and an operation of the memory cell MC of the fifth embodiment;

FIG. 22A is a cross-sectional view taken along line A-A′ in FIG. 18 to illustrate a manufacturing method for the memory device according to the fifth embodiment;

FIG. 22B is a cross-sectional view taken along line B-B′ in FIG. 18 to illustrate a manufacturing method for the memory device according to the fifth embodiment;

FIG. 22C is a cross-sectional view taken along line C-C′ in FIG. 18 to illustrate a manufacturing method for the memory device according to the fifth embodiment; and

FIG. 23 is a diagram for describing a configuration and an operation of the memory cell MC of a sixth embodiment.

### DETAILED DESCRIPTION

According to one embodiment, a memory device includes a first gate electrode, a second gate electrode and a third gate electrode on a substrate. The first gate electrode, the second gate electrode and the third gate electrode extend in a first direction that is parallel to the substrate. The first gate electrode, the second gate electrode and the third gate electrode are provided in order thereof apart from each other in a second direction that is parallel to the substrate and crosses the first direction. The memory device includes a first active area and a second active area on the substrate. The first active area crosses the first gate electrode, the second gate electrode and the third gate electrode, and extends in the second direction. The second active area is provided apart from the first active area in the first direction. The second active area crosses the first gate electrode, the second gate electrode and the third gate electrode. The second active area is electrically insulated from the first active area and extends in the second direction. The memory device includes a first contact, a second contact, a third contact and a fourth contact. The first contact is electrically connected to the first active area between the first gate electrode and the second gate electrode. The second contact is electrically connected to the first active area between the second gate electrode and the third gate electrode. The third contact is electrically connected to the second active area between the first gate electrode and the second gate electrode. The fourth contact is electrically connected to the second active area between the second gate electrode and the third gate electrode. The memory device also includes a variable resistance layer extending in the first direction, a first interconnection layer extending in the first direction, a second interconnection layer above the first interconnection layer and a third interconnection layer above the first interconnection layer. The variable resistance layer is connected to the first contact and the second contact on the lower surface, and connected to the first interconnection layer on the upper surface. The second interconnection layer is electrically connected to the second contact and extends in the second direction. The third interconnection layer is electrically connected to the fourth contact and extends in the second direction.

Hereinafter, embodiments of the invention will be described with reference to the drawings.

In the following description, a semiconductor substrate side will be mentioned while being referred to as a lower side, for convenience. Moreover, in the specification, the term “intersect” denotes that two lines cross each other.

### First Embodiment

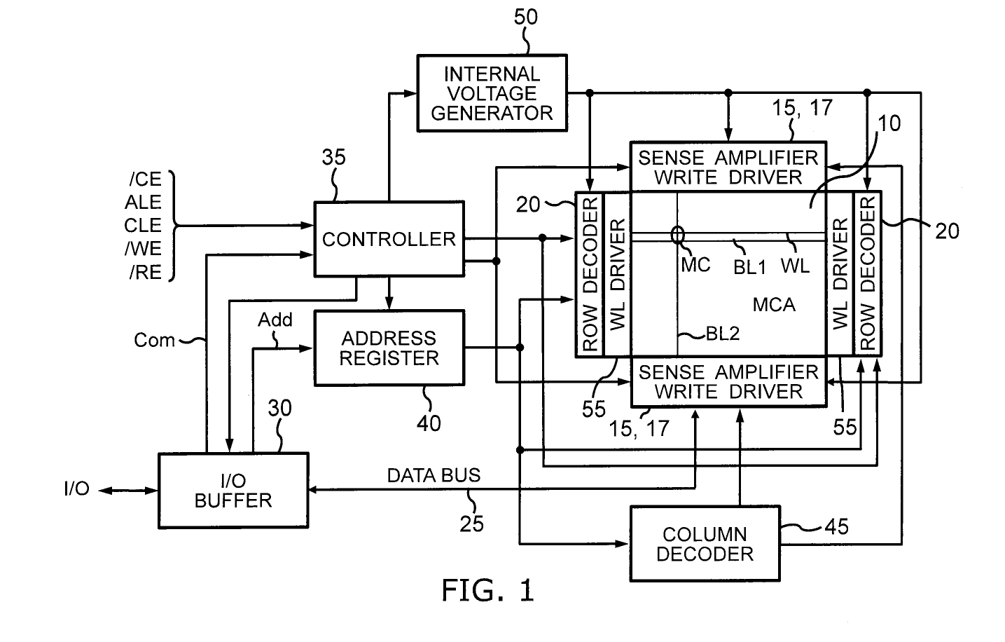

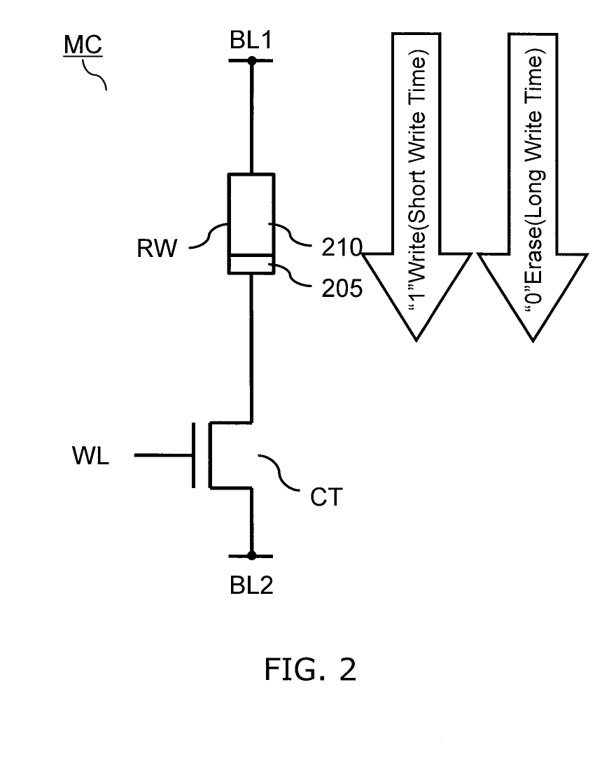

FIG. 1 is a block diagram showing a configuration of a resistance change-type memory of a first embodiment. In a memory cell array 10, a plurality of memory cells MC are arranged in a matrix. As shown in FIG. 2, each memory cell MC includes a variable resistance element RW and a cell transistor CT. The variable resistance element RW is an element which stores data in response to a change of a resistance state and in which data is rewritable by using a current. The cell transistor CT is provided to correspond to the variable resistance element RW. When the cell transistor CT is in a conduction state, a current flows in the corresponding variable resistance element RW.

In the memory cell array 10, a plurality of word lines WL extend in a row direction (a first direction). A plurality of first bit lines BL1 extend in the row direction, and a second bit line BL2 extends in a column direction (a second direction). The second bit line BL2 extends so as to intersect, that is, to cross the first bit line BL1 and the word line WL. The memory cell MC is provided to correspond to an intersection point of the second bit line BL2 and the word line WL. The variable resistance element RW and the cell transistor CT in each memory cell MC are connected to each other in series. The variable resistance element RW is connected to the first bit line BL1, and the cell transistor CT is connected to the second bit line BL2. A gate electrode of the cell transistor CT is connected to the word line WL.

For example, a sense amplifiers 15 and a write-drivers 17 are arranged on both sides of the memory cell array 10 in a second bit line direction. The sense amplifier 15 is connected to a bit line BL and reads out data stored in the memory cell MC by detecting a current flowing in the memory cell MC which is connected to a selection word line WL. The write-driver 17 is connected to the bit line BL and writes data by causing a current to flow in the memory cell MC which is connected to the selection word line WL. The sense amplifier 15 and the write-driver 17 may be provided on both sides thereof in a first bit line direction, without being limited to both the sides thereof in the second bit line direction.

A row decoders 20 and a word line drivers 55 are respectively arranged on both sides of the memory cell array 10 in a word line direction. The word line driver 55 is connected to the word line WL and applies a voltage to the selection word line WL at the time of data reading or data writing.

A data transfer between the sense amplifier 15 or the write-driver 17 and an external input/output terminal I/O is performed via a data bus 25 and an I/O buffer 30.

Various external control signals such as a chip enable signal/CE, an address latch enable signal ALE, a command latch enable signal CLE, a write enable signal/WE, and a read-out enable signal/RE are input in a controller 35. The controller 35 distinguishes an address signal Add and a command signal Com which are supplied from the external input/output terminal I/O, based on the control signals thereof. Then, the controller 35 transmits the address signal Add to the row decoder 20 and a column decoder 45 via an address resistor 40. The controller 35 decodes the command signal Corn. The sense amplifier 15 applies a voltage to the bit line BL in accordance with a column address decoded by the column decoder 45. The word line driver 55 applies a voltage to the word line WL in accordance with a row address decoded by the row decoder 20.

The controller 35 performs each of sequential controls of data reading, data writing and erasing in accordance with the address signal Add and the command signal Corn. An internal voltage generation circuit 50 generates an internal voltage (for example, a voltage obtained by boosting a power supply voltage supplied from outside the resistance change-type memory) which is necessary for each operation. The internal voltage generation circuit 50 is also controlled by the controller 35, thereby generating a necessary voltage.

FIG. 2 is a diagram describing an operation and a configuration of the memory cell MC of the embodiment. In the embodiment, the variable resistance element RW of the memory cell MC is connected to the first bit line BL1 and the cell transistor CT. The cell transistor CT is connected to the variable resistance element RW and the second bit line BL2.

As an example of the variable resistance element RW, FIG. 2 shows a super-lattice phase change memory element.

In the super-lattice phase change memory element, a crystalline structure of a super-lattice varies by being applied with electric energy so as to be able to be in a low-resistance state and a high-resistance state. Here, data of 1-bit can be stored in the super-lattice phase change memory element by defining the low-resistance state as data “1” and defining the high-resistance state as data “0”. The low-resistance state may be defined as “0” and the high-resistance state may be defined as “1”.

For example, as shown in FIG. 2, the super-lattice phase change memory element includes a super-lattice layer 110 in which an orientation layer 105, a first crystal layer, and a second crystal layer are used, for example. As necessary, the super-lattice phase change memory element includes an electrode layer (not illustrated).

Characteristics of the orientation layer 105 are improving orientation of the super-lattice layer 110. For example, the orientation layer 105 includes a crystalline structure of hexagonal crystal. Specifically, the orientation layer 105 includes a chalcogen compound having antimony and tellurium as main components, or a chalcogen compound having bismuth and tellurium as main components.

In the super-lattice layer 110, the first crystal layer and the second crystal layer are alternately stacked.

In the first crystal layer, positions of constituent atoms are reversibly transitional by being applied with electric pulses. For example, in the first crystal layer, a chalcogen compound having germanium and tellurium as main component is used.

The second crystal layer is a layer which assists atomic transition of the first crystal layer. Although a crystalline structure of the second crystal layer is not necessarily transitional, the crystalline structure thereof may be transitional. For example, in the second crystal layer, a chalcogen compound having antimony as a main component, or the chalcogen compound having bismuth and tellurium as the main component is used.

The super-lattice phase change memory element performs a writing operation (transition from data “0” to “1”) and an erasing operation (transition from data “1” to “0”) by adding electric energy, for example. Here, the term “electric energy” denotes integral calculus regarding a period of electricity.

In the super-lattice phase change memory element, the erasing operation requires electric energy greater than that in the writing operation. Therefore, a method of increasing a voltage applied at the time of erasing than a voltage applied at the time of writing, or a method of lengthening an applying period at the time of erasing than an applying period at the time of writing can be exemplified.

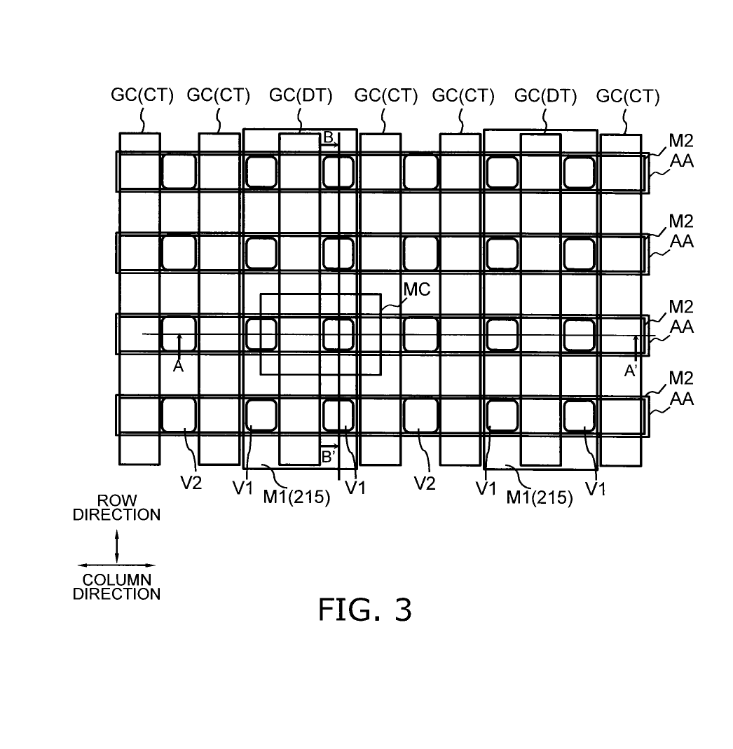

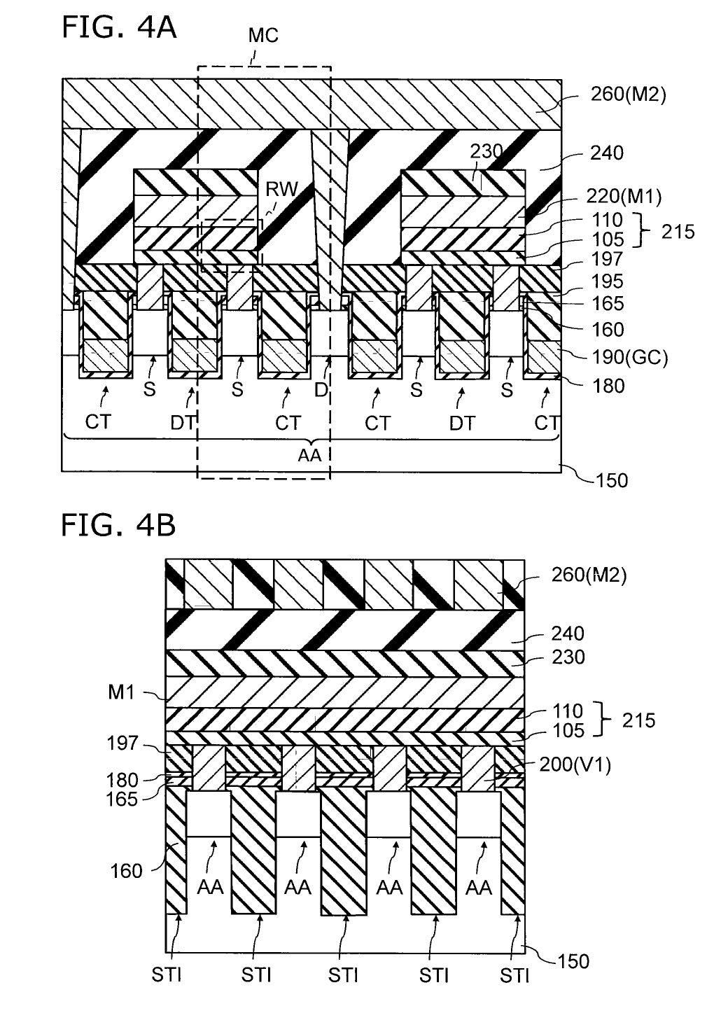

FIG. 3 is a layout of the resistance change-type memory according to the first embodiment. FIG. 4A is a cross-sectional view taken along line A-A in FIG. 3. FIG. 4B is a cross-sectional view taken along line B-B in FIG. 3.

In the following description, a extending direction of a gate electrode GC and a first interconnection layer M1 is referred to as the row direction (the first direction). A extending direction of a second interconnection layer M2 and an active area AA, being substantially orthogonal to the first direction is referred to as the column direction (the second direction).

Firstly, the cross-sectional views of the embodiment will be described with reference to FIGS. 4A and 4B. FIG. 4A is the cross-sectional view when the active area AA is seen in the row direction.

As shown in FIG. 4A, a plurality of cell transistors (first transistor) CT and the dummy transistor (second transistor) DT are provided in the active area AA. On both sides of the cell transistor CT, the cell transistor CT and the dummy transistor DT are respectively provided. On both sides of the dummy transistor DT, two cell transistors CT are respectively provided. The cell transistor CT, the dummy transistor DT, the cell transistor CT are periodically provided.

The cell transistor CT includes the gate electrode GC and a gate insulation film 180 which are embedded in the semiconductor substrate 150. n+ type source region S and drain region D are included on both sides of the gate electrode GC in the cell transistor CT. Access to the variable resistance element RW can be executed by driving the cell transistor CT.

The dummy transistor DT includes the gate electrode GC and the gate insulation film 180 which are embedded in the semiconductor substrate 150. The n+ type source regions S of the cell transistors CT are provided on both sides of the gate electrode GC in the dummy transistor DT.

The drain region D of the cell transistor CT is electrically connected to the second interconnection layer M2 via a second contact V2. The second interconnection layer M2 forms the second bit line BL2.

The source region S of the cell transistor CT is electrically connected to a lower side portion of a variable resistance layer 215 via a first contact V1.

The variable resistance layer 215 includes the orientation layer 105 and the super-lattice layer 110. An upper part of the super-lattice layer 110 is electrically connected to the first interconnection layer M1. The first interconnection layer M1 forms the first bit line BL1.

The variable resistance layer 215 stores the data of 1-bit for one combination of the first contact V1 and the first interconnection layer M1. A partial region of the variable resistance layer 215 storing the data of 1-bit is the variable resistance element RW. In FIG. 4A, two first contacts V1 are connected to one variable resistance layer 215. In other words, there are provided two variable resistance elements RW for one variable resistance layer 215.

Actually, as described below, since a plurality of the first contacts V1 are connected to one variable resistance layer 215, one variable resistance layer 215 includes as many of the variable resistance elements RW as the connected first contact V1.

Connection relationships described above in FIG. 4A can be summarized as follows with respect to the memory cell MC.

The second interconnection layer M2 which is the second bit line BL2 is electrically connected to the drain region D of the cell transistor CT through the second contact V2. The source region S of the cell transistor CT is connected to the variable resistance element RW through the first contact V1. An upper portion of the variable resistance element RW is connected to the first interconnection layer M1 which is the first bit line BL1.

FIG. 4B is a cross-sectional view of a region where the first contacts V1 are formed, viewed in the column direction.

The active area AA and an element isolation region STI (shallow trench isolation) are formed in the semiconductor substrate 150.

The first contacts V1 are formed in the active area AA. Upper ends of the first contacts V1 are connected to a lower portion of the variable resistance layer 215.

As shown in FIG. 4B, the variable resistance layer 215 and the first interconnection layer M1 which is on the upper layer of the variable resistance layer are continuously formed in the row direction.

A layout of the embodiment will be described with reference to FIG. 3. FIG. 3 shows a portion taken out from a memory cell array. The active area AA, the gate electrode GC, the first interconnection layer M1, and the second interconnection layer M2 in the illustration can extend so as to exceed the frame of FIG. 3.

The active areas AA respectively extend in the column direction and are spaced at predetermined intervals in the row direction. The gate electrodes GC respectively extend in the row direction and are spaced at predetermined intervals in the column direction.

In other words, each active area AA is provided to be substantially orthogonal to each gate electrode and parallel in the column direction. Then, the cell transistors CT and the dummy transistor DT are provided at an intersection point of the gate electrodes GC and the active areas AA.

A gate electrode GC (CT) which configures the cell transistor CT is formed on both sides of a gate electrode GC (DT) which configures the dummy transistor DT. The gate electrode GC (CT) which configures the cell transistor CT and the gate electrode GC (DT) which configures the dummy transistor DT are formed on both sides of the gate electrode GC (CT) which configures the cell transistor CT. In other words, the gate electrode GC (CT), the gate electrode GC (DT), and the gate electrode GC (CT) are repeatedly formed. More specifically, in a major portion of the memory cell array, the gate electrodes GC are formed by repeating GC (CT), GC (DT), GC (CT), GC (CT), GC (DT), GC (CT), and so forth in the column direction.

In the active area AA, the first contact V1 is formed between the gate electrode GC (DT) and the gate electrode GC (CT). Then, the first interconnection layer M1 and the variable resistance layer 215 extend in the row direction in a width covering the plurality of first contacts V1 that provided between one gate electrode GC (DT) and one gate electrode GC (CT), and the plurality of first contacts V1 that provided between the gate electrode GC(DT) and another gate electrode GC(CT). However, each of the first contacts V1 may be partially covered instead of being completely covered.

In the active area AA, the second contact V2 is formed between the gate electrode GC (CT) and the gate electrode GC (CT). Then, the second interconnection layer M2 electrically connects to a plurality of the second contacts V2 provided in one active area AA. The second interconnection layer M2 extends in the column direction.

Here, the second contact V2 has a size on an active area, for example, a major axis of an elliptical or oval shape greater than that of the first contact V1.

The memory cell MC of the variable resistance element RW according to the embodiment has an extremely small size, such as 6F² (3F×2F). Here, “F” denotes the minimum processing size when a lithographic technology and an etching technology are used.

Writing and reading operations of data with respect to a selection memory cell MC are performed as follows. The word line WL connected to the gate electrode GC of the cell transistor CT included in the selection memory cell MC is referred to as the selection word line WL. Moreover, bit lines BL1 and BL2 connected to the selection memory cell MC are referred to as selection bit lines.

Firstly, a first voltage is applied between the selection bit lines BL1 and BL2. Then, a second voltage is applied to the selection word line WL. The cell transistor CT relevant to the selection memory cell MC is driven by applying the second voltage to the selection word line WL. As the cell transistor CT is driven, a first voltage between the selection bit lines BL1 and BL2 is applied to the variable resistance element RW relevant to the selection memory cell MC. Accordingly, a current corresponding to the first voltage flows in the variable resistance element RW, and thus, it is possible to perform writing and reading with respect to the variable resistance element RW.

During the writing and reading operations, it is desired that 0 V or a negative potential is applied to the gate electrode GC of the dummy transistor DT so as not to be driven in order to prevent an erroneous operation in an adjacent memory cell MC. However, when simultaneously performing writing and erasing with respect to the plurality of memory cells MC which are formed in the same variable resistance element RW, it is possible to apply a positive potential to the gate electrode GC of the dummy transistor DT so as to drive the dummy transistor DT.

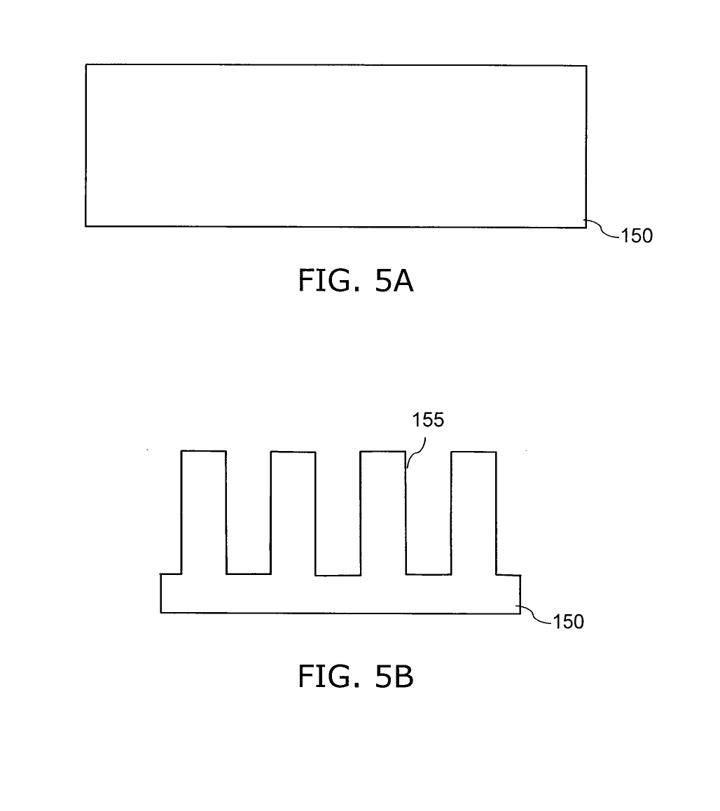

Hereinafter, a manufacturing method of the first embodiment will be described with reference to FIGS. 5A and 5B to 13A and 13B.

In the below-described manufacturing method, when there is only one diagram for the reference drawing and unless otherwise specifically denoted, the one diagram corresponds to the cross-sectional view taken along line A-A in FIG. 3. In addition, when two diagrams having reference signs of A and B are present for the reference diagram, the two diagrams respectively correspond to the cross-sectional view taken along line A-A in FIG. 3 and the cross-sectional view taken along line B-B in FIG. 3.

As shown in FIGS. 5A and 5B, the semiconductor substrate 150 is etched, thereby forming a trench 155.

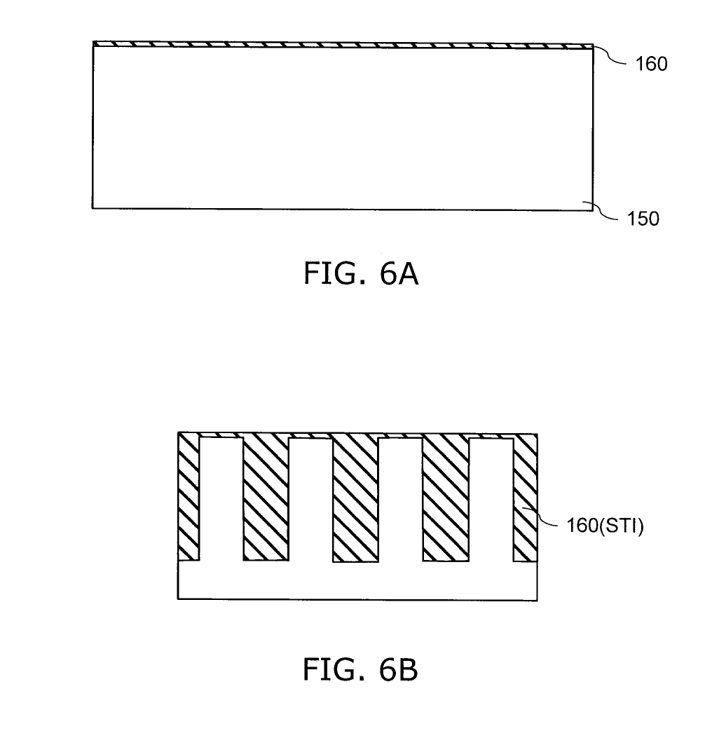

As shown in FIGS. 6A and 6B, an element isolation insulation film 160 is embedded and flattened so as to fill into the trench 155. As a result of flattening, the element isolation region STI is formed. For example, flattening is performed by a reactive ion etching (RIE) method or a chemical mechanical polishing (CMP) method. Regions other than the element isolation region STI are referred to as the active areas AA.

As shown in FIG. 7, a first interlayer insulation film 165 is formed, and then, etching is performed to form a trench 170 for forming a gate electrode. Thereafter, a mask pattern and a mask material are removed.

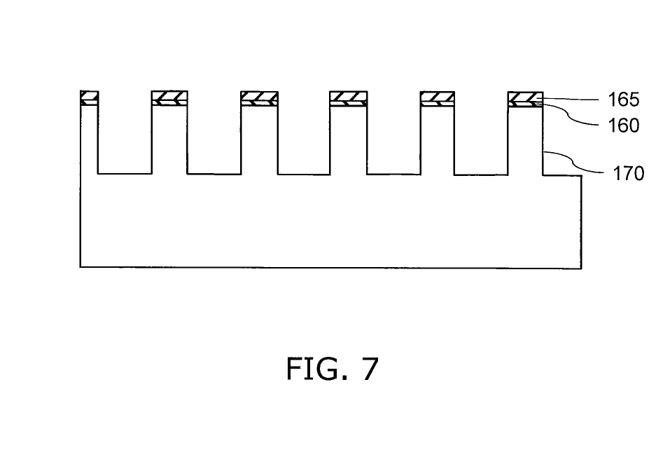

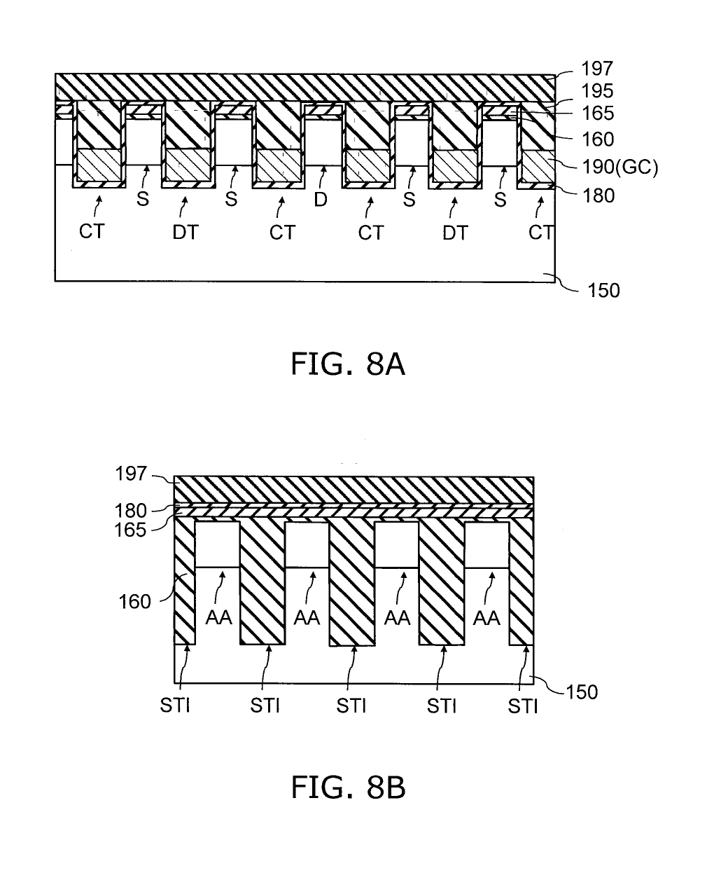

Thereafter, the gate electrode GC and the n+ type source region S and drain region D shown in FIGS. 8A and 8B are formed. Firstly, the gate insulation film 180 and a gate electrode layer 190 are deposited and removed to a predetermined height by performing etch-back. Thereafter, a CMP stopper film 195 is deposited, and flattening is performed by the RIE method or the CMP method. Then, impurity elements are implanted so as to form source regions and drain regions. Thereafter, a second interlayer insulation film 197 is deposited. Accordingly, an embedded-type cell transistor CT is formed.

The gate insulation film 180 is deposited by a thermal oxidation method and the like using a silicon oxide film, a silicon nitride film, and a silicon oxy-nitride film, for example. The gate electrode layer 190 is formed using polycrystal silicon, tungsten, copper, and metal silicide, for example. As a deposition method, a plasma CVD method, a metal plating method, a sputtering method, and the like are used in accordance with the material thereof. The CMP stopper film 195 is formed using a silicon nitride film, for example. The second interlayer insulation film 197 is formed using a silicon oxide film, for example.

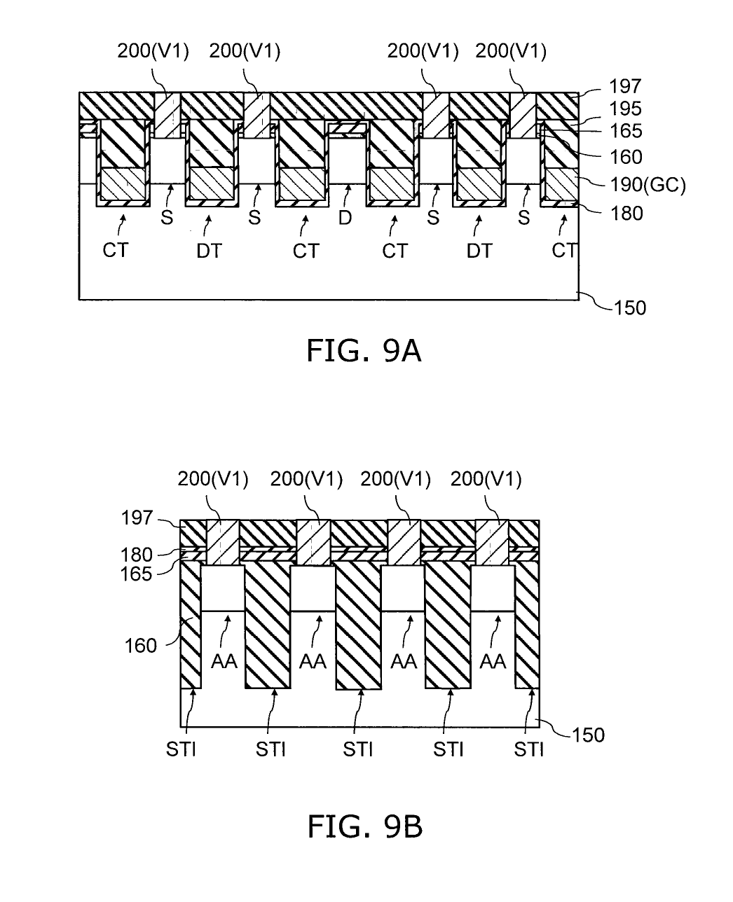

The first contacts V1 shown in FIGS. 9A and 9B are formed. In other words, a desired mask pattern is formed on the second interlayer insulation film 197, thereby forming etching while having the mask pattern as a mask. As a result of etching, a first contact hole reaching the source region S is formed. After a first contact material 200 is deposited, materials in portions other than the first contact hole are removed by the CMP method. Accordingly, the first contacts V1 are formed.

For example, the first contact material 200 includes a barrier metallic layer and a metallic layer. The barrier metallic layer is formed using titanium, tantalum, niobium, titanium nitride, tantalum nitride, niobium nitride, or a stacked layer thereof, for example. The metallic layer is formed using tungsten, copper, aluminum, and the like.

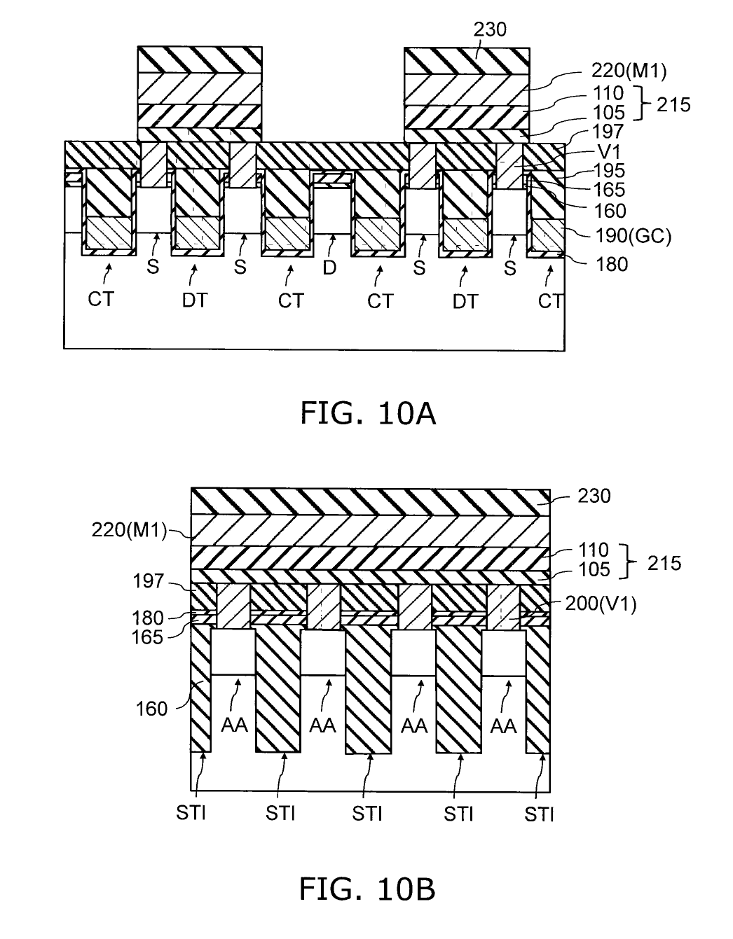

The variable resistance layer 215 and the first interconnection layer M1 shown in FIGS. 10A and 10B are formed.

Firstly, the orientation layer 105, the super-lattice layer 110, a first interconnection layer material 220, and a hard mask 230 are deposited in order. A desired mask pattern is formed on the hard mask 230 by a lithography method. While having the mask pattern as a mask, etching is performed by the RIE method so as to reach the second interlayer insulation film 197.

The orientation layer 105 is formed using the chalcogen compound having antimony and tellurium as the main components, or the chalcogen compound having bismuth and tellurium as the main components, for example.

In the super-lattice layer 110, the first crystal layer and the second crystal layer are alternately stacked. The first crystal layer is formed using the chalcogen compound having germanium and tellurium as the main components, for example. The second crystal layer is formed using the chalcogen compound having antimony as the main component, or the chalcogen compound having bismuth and tellurium as the main components, for example. An upper electrode layer is formed using a metallic layer of tungsten, for example.

For example, the first interconnection layer material 220 includes the barrier metallic layer and the metallic layer. The barrier metallic layer is formed using titanium, tantalum, niobium, titanium nitride, tantalum nitride, niobium nitride, or a stacked layer thereof, for example. The metallic layer is formed using tungsten, copper, aluminum, and the like. The hard mask 230 is formed using a silicon oxide film, a silicon nitride film, polycrystal silicon, carbon, or a stacked layer thereof, for example, and is deposed by the plasma CVD method.

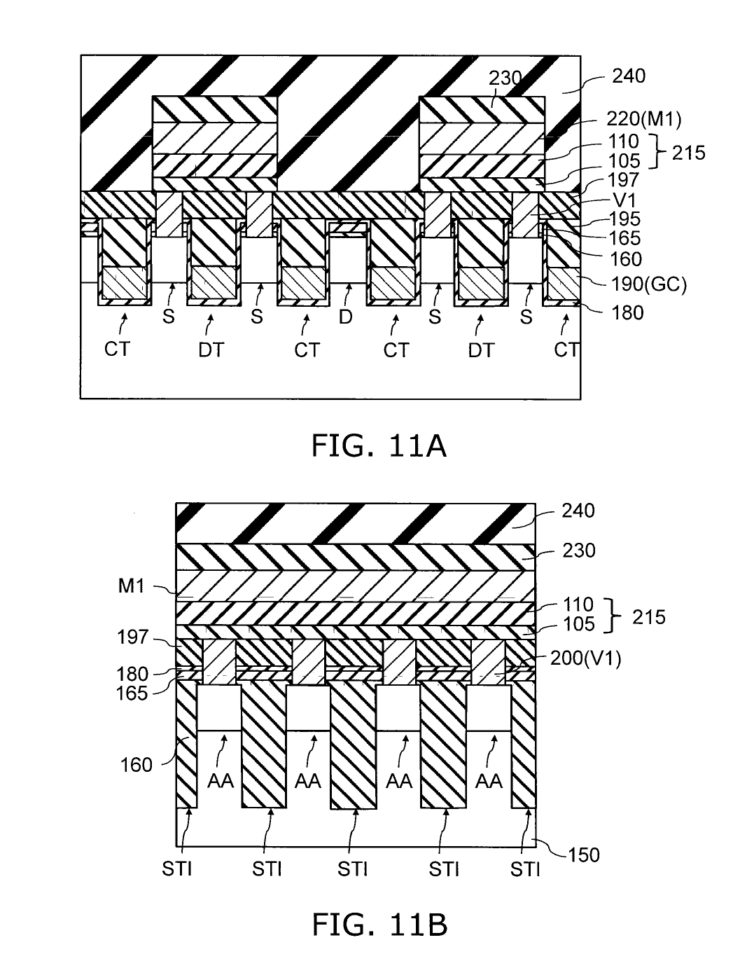

As shown in FIGS. 11A and 11B, after the third interlayer insulation film 240 is deposited, the third interlayer insulation film 240 is flattened by the CMP method. The third interlayer insulation film 240 is formed using a silicon oxide film, for example.

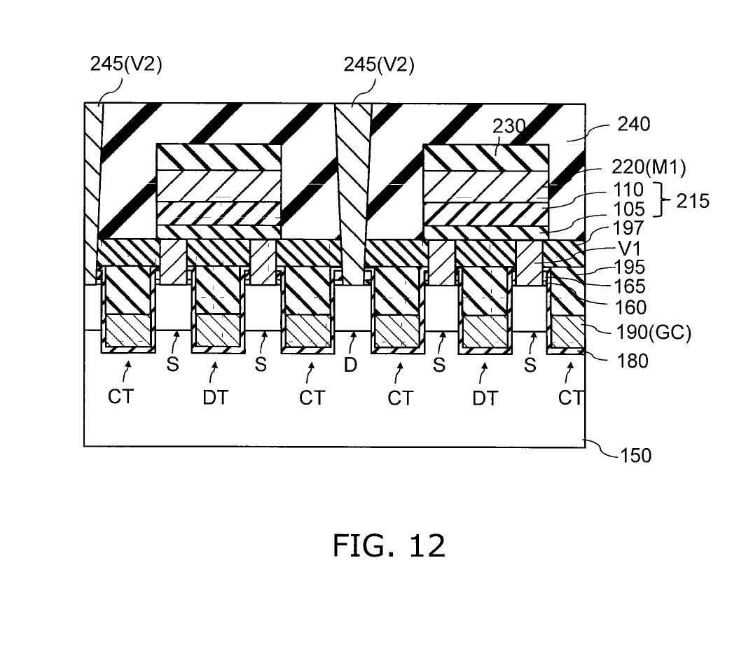

Next, the second contact V2 shown in FIG. 12 is formed. A desired mask pattern is formed on the third interlayer insulation film 240. While having the mask pattern as a mask, a second contact hole is subjected to etching so as to reach the drain region D.

A second contact material 245 is deposited, and then, the second contact material 245 in portions other than the second contact hole is removed by the CMP method.

Here, since the height of the second contact V2 is higher than that of the first contact V1, the first contact V1 on the active area has a size, for example, the major axis of an elliptical or oval shape greater than that of the second contact V2.

The second contact material 245 includes the barrier metallic layer and the metallic layer, for example. The barrier metallic layer is formed using titanium, tantalum, titanium nitride, tantalum nitride, or a stacked layer thereof, for example. The metallic layer is formed using tungsten, copper, and the like.

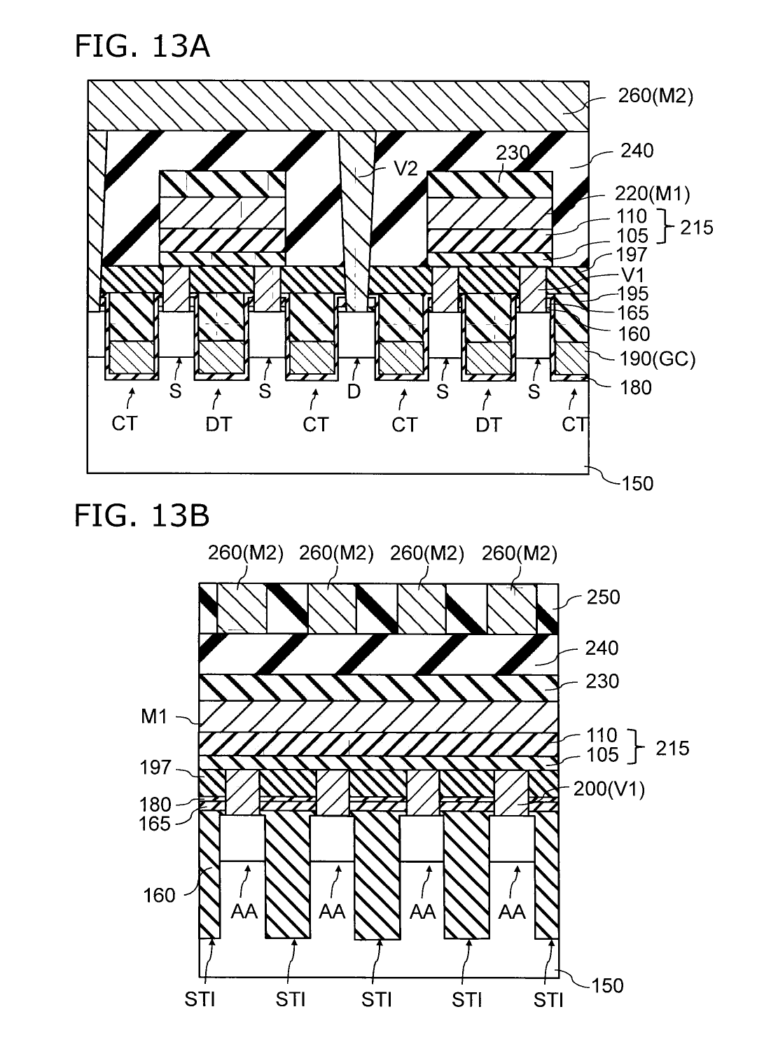

The second interconnection layer M2 shown in FIGS. 13A and 13B is formed. Firstly, a fourth interlayer insulation film 250 is deposited, and then, a desired mask pattern is formed by the lithography method. While having the mask pattern as a mask material, etching is performed so as to reach an upper portion of the second contact V2, thereby forming the second interconnection trench. A second interconnection layer material 260 is deposited, and then, the second interconnection layer material 260 in portions other than the second interconnection trench is removed by the CMP method. Accordingly, the second interconnection layer M2 is formed.

The fourth interlayer insulation film 250 is formed using a silicon oxide film, for example. The second interconnection layer material 260 is formed using a material similar to that of the first interconnection layer M1.

Subsequently, using a general manufacturing method, various interconnection layers and circuit elements are formed. In this manner, the resistance change-type memory of the embodiment is manufactured.

According to the example described above, the active area AA can be formed in line without being divided. In other words, there is no need to divide the active area AA into island shapes so as to correspond to several memory cells.

For example, in order to prevent an erroneous operation of an adjacent memory cell MC, it can be considered to form the active area AA by dividing the active area AA into the island shapes so as to correspond to one or several memory cells MC. In order to form a pattern in fine island shapes, it can be considered to separately perform processing of line dividing after performing processing in line. In this case, even though forming is attempted through independent processing, it is difficult to form a mask pattern and to form a desired pattern through etching thereafter.

In the embodiment, since it is acceptable as long as the active area AA is formed in line, line dividing can be omitted. A lithography process, etching, and the like can be curtailed by being able to omit the line dividing. Curtailment of processes leads to reduction of material costs and indirect costs of manufacturing. Moreover, curtailment of processes allows an improvement of yield and cost reduction, and thus, inexpensive memories can be supplied.

As shown in FIGS. 3, 4A, and 4B, the dummy transistor DT is formed between the memory cell MC and an adjacent memory cell MC. Then, the gate electrode GC (DT) of the dummy transistor DT extends in the row direction.

On account of presence of the dummy transistor DT, the memory cell MC can be electrically isolated from the adjacent memory cell MC. Since electrical isolation therebetween is possible, the active area AA can be formed in line.

Both the gate electrode GC (CT) and the gate electrode GC (DT) are spaced at predetermined intervals. By spaced the gate electrode GC at predetermined intervals, forming and etching of the mask pattern can be easily performed.

Easily performed manufacturing leads to an improvement of yield, and thus, possibilities to supply inexpensive memories can be further enhanced.

Subsequently, a variation of the first embodiment will be described.

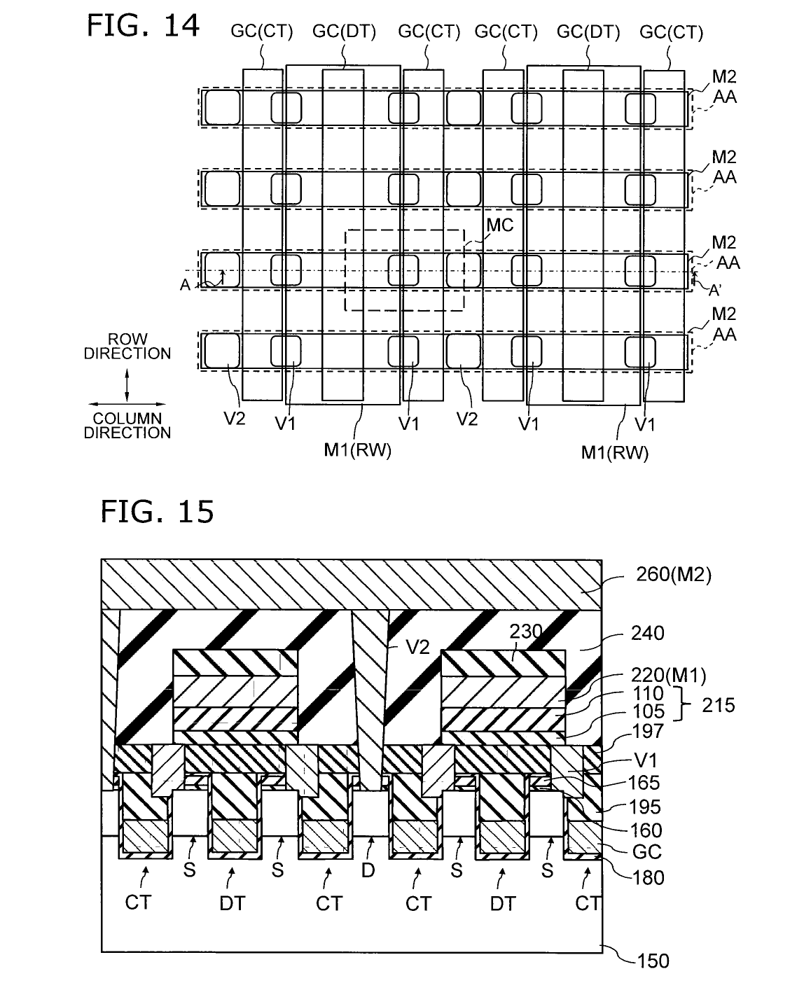

FIG. 14 shows a layout of the resistance change-type memory according to the variation of the first embodiment. FIG. 15 is a cross-sectional view taken along line A-A in FIG. 14.

In the variation, the first contact V1 is formed to be deviated by a predetermined distance in a direction of the most contiguous gate electrode GC (CT). For example, the predetermined distance is a half pitch F_{GC} of the gate electrode (half the sum of the width of the gate electrode GC and a space between the gate electrodes GC). In other words, the first contacts V1 are formed on the active area AA and the gate electrode GC.

In accordance with the arrangement of the first contacts V1 as described above, the first contacts V1 are arranged at substantially equivalent intervals in the column direction. As conditions in etching during a process of the first contact hole are optimized, it is possible to form the gate electrode GC so as not to come into contact with the first contact.

In both cases of the variation and the first embodiment, since the first contacts are formed on the active area AA, the first contacts are arranged at substantially equivalent intervals in the row direction.

Therefore, according to the variation, the first contacts V1 are respectively arranged at substantially equivalent intervals in the row direction and at substantially equivalent intervals in the column direction. In accordance with the arrangement at substantially equivalent intervals, it is possible to suppress unevenness of size of the first contacts V1 during a manufacturing process of the first contacts V1. Accordingly, unevenness of electrical resistance values of the first contacts V1 can be decreased. Ultimately, unevenness of electrical properties between the memory cells MC can be suppressed. In addition, when the first contacts V1 are arranged at substantially equivalent intervals, forming of the mask pattern by the lithography method and etching by the RIE method can be easily performed. In other words, even though sizes of the first contacts V1 are micronized, it is possible to manufacture the first contacts V1 more easily.

As another variation, the half pitch F_{GC} of the gate electrode (half the sum of the width of the gate electrode GC and the space between the gate electrodes GC) and a half pitch F_{M2} of the second interconnection layer (half the sum of the width of the second interconnection layer M2 and the space between the second interconnection layers M2) may be arbitrarily sized. FIG. 3 is a diagram showing that the half pitch F_{GC} of the gate electrode is caused to be substantially the same as the half pitch F_{M2} of the second interconnection layer.

Some other variations will be described.

Although the source regions S of the cell transistors CT are illustrated to be provided on both the sides of the gate electrode GC in the dummy transistor DT in the above description, the drain region D may be provided on both the sides of the gate electrode GC in the dummy transistor DT. In other words, in the above description, the drain region D may be replaced by the source region S.

The first interconnection layer M1 is the second bit line BL2, and the second interconnection layer M2 is the first bit line BL1. The first interconnection layer M1 may be the first bit line BL1, and the second interconnection layer M2 may be the second bit line BL2.

The orientation layer 105 and the super-lattice layer 110 may be switched to be upside down.

### Second Embodiment

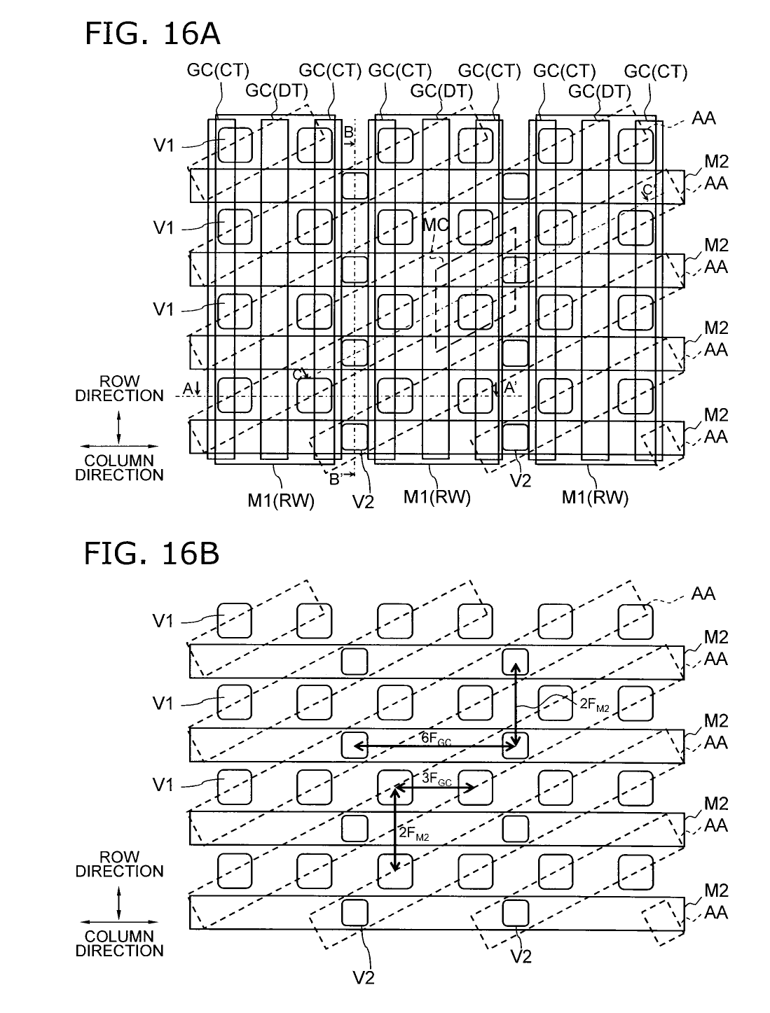

FIGS. 16A and 16B illustrate layouts of a second embodiment. In FIG. 16B, illustrations of the gate electrode GC, the first interconnection layer M1, and the variable resistance element RW of FIG. 16A are omitted so as to be easily recognized.

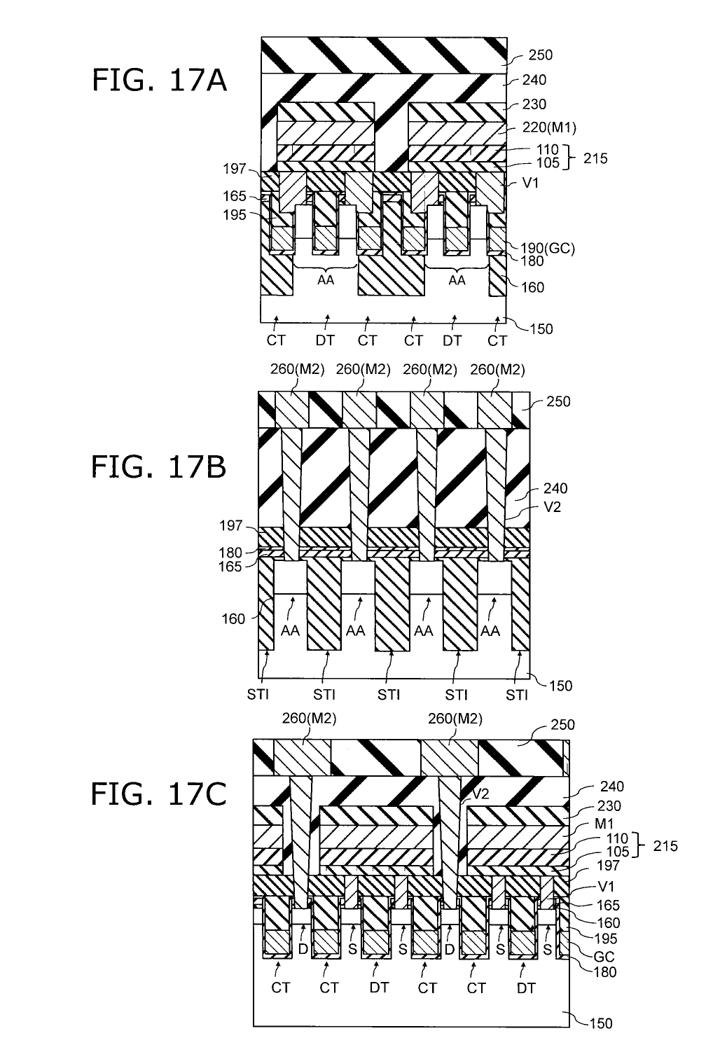

FIG. 17A is a cross-sectional view taken along line A-A′ in FIG. 16A. FIG. 17B is a cross-sectional view taken along line B-B′ in FIG. 16A. FIG. 17C is a cross-sectional view taken along line C-C′ in FIG. 16A.

The embodiment is different from the first embodiment in several aspects.

The first contacts V1 are arranged in a manner similar to that of the variation of the first example, thereby being formed at substantially equivalent intervals in each of the column direction and the row direction. As shown in FIG. 16B, the first contacts V1 are formed at intervals of 3 F_{GC} in the column direction and at intervals of 2 F_{M2} in the row direction.

The gate electrodes and the second interconnection layers are formed so that the half pitch F_{GC} of the gate electrode and the half pitch F_{M2} of the second interconnection layer has a relation of 3 F_{GC}=F_{M2}. Accordingly, the first contacts V1 are formed at predetermined intervals which are substantially the same in the column direction and the row direction.

The active area AA is formed to have an angle with respect to both the row direction and the column direction. Therefore, the second contacts V2 formed in the same active area AA are respectively connected to the different second interconnection layers M2.

The angle of the active area AA can be obtained as described below, for example. A distance between the second contact V2 and an adjacent second contact V2 on the same active area AA is 6 F_{GC} in the column direction and 2 F_{M2} in the row direction.

As described above, there is a relationship of 3 F_{GC}=2 F_{M2} between the half pitch F_{GC} of the gate electrode and the half pitch F_{M2} of the second interconnection layer. Therefore, the angle of the active area AA with respect to the column direction becomes a tan (2 F_{M2}/6 F_{GC})=a tan (½)=approximately 26.5 degrees.

Next, a connection relationship of the memory cell MC in the second embodiment is summarized as below based on FIG. 17C.

The second interconnection layer M2 which is the second bit line BL2 is electrically connected to the drain region D of the cell transistor CT through the second contact V2. The source region S of the cell transistor CT is connected to the variable resistance element RW through the first contact V1. The upper portion of the variable resistance element RW is connected to the first interconnection layer M1 which is the first bit line BL1.

In other words, the connection relationship of the cross-sectional view of FIG. 17C is similar to that of FIG. 4A.

As shown in FIGS. 3, 16A, and 16B, the active area AA is formed to have an angle in the second embodiment. Therefore, in contrast with the first embodiment, positions of two first contacts V1 in the row direction electrically connected from the second contact via the cell transistor CT are different from each other.

According to the above-described second embodiment as well, the effect similar to that of the first embodiment can be achieved. In other words, the active areas AA can be formed in line at predetermined intervals without being divided, and the gate electrodes GC can be formed in line at predetermined intervals.

Moreover, as the half pitch F_{GC} of the gate electrode and the half pitch F_{M2} of the second interconnection layer are formed under the relationship of 3 F_{GC}=2 F_{M2}, the first contacts V1 can be formed at approximately equivalent intervals in both the row direction and the column direction.

In other words, in processing of the first contacts V1, unevenness of size can be suppressed, denoting that unevenness of characteristics between the memory cells MC can be suppressed. Moreover, even though a distance between the first contacts V1 is decreased, processing can be performed more easily.

According to the embodiment, a width of the active area AA or an interval with respect to an adjacently positioned active area AA can be increased further than that of the first embodiment. An increase in the width of the active area AA results in an increase of a channel width of the cell transistor CT which is formed on the active area AA. A current flowing in the cell transistor CT is substantially proportional to the channel width. Therefore, when the same voltage as the first embodiment is applied to the cell transistor CT, a current flowing in the cell transistor CT increases. In other words, more current can flow in the variable resistance element RW, and thus, reading and writing operations of the variable resistance element RW can increase in speed. As the operations of the variable resistance element RW increase in speed, it is possible to obtain memories capable of a high-speed operation.

### Third Embodiment

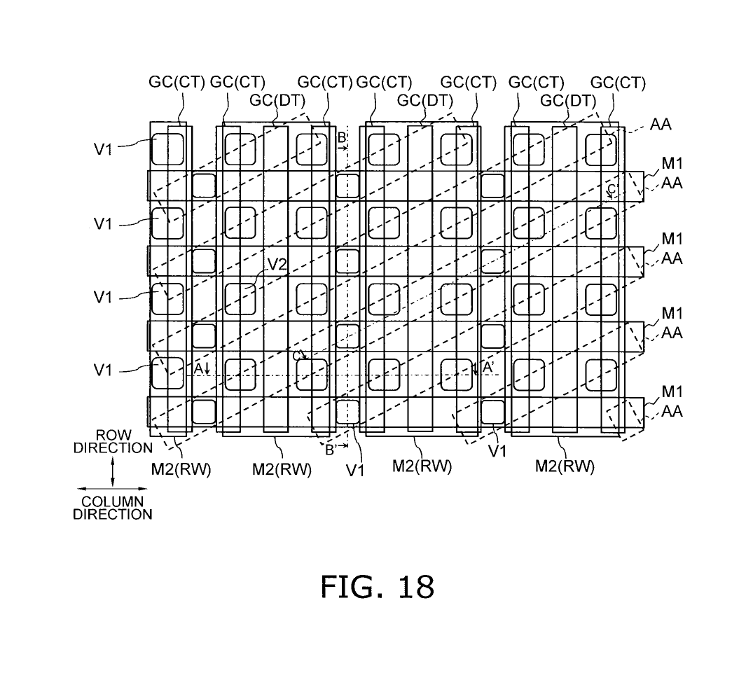

FIG. 18 illustrates a layout of a third embodiment of the invention.

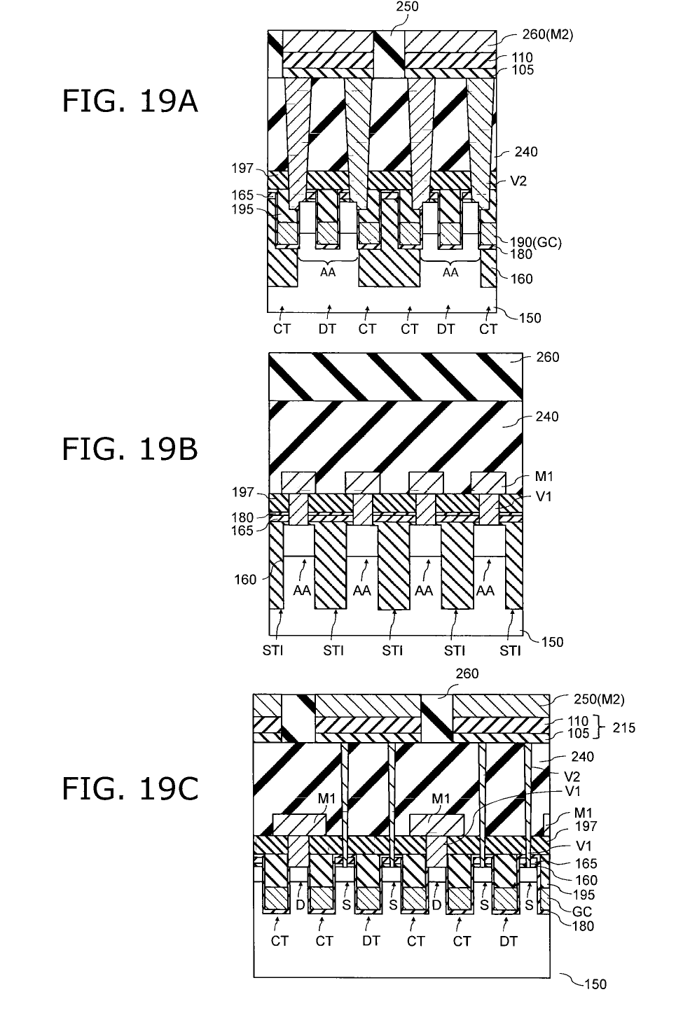

FIG. 19A is a cross-sectional view taken along line A-A′ of FIG. 18. FIG. 19B is a cross-sectional view taken along line B-B′ of FIG. 18. FIG. 19C is a cross-sectional view taken along line C-C′ of FIG. 18.

The third embodiment is different from the second embodiment in that the first interconnection layer M1 and the second interconnection layer M2 of the second embodiment are switched, and the orientation layer 105 and the super-lattice layer 110 are formed under the second interconnection layer M2.

Similar to the first embodiment and the second embodiment, the active areas AA can be formed in line at predetermined intervals without being divided, and the gate electrodes GC can be formed in line at predetermined intervals in the third embodiment as well.

### Fourth Embodiment

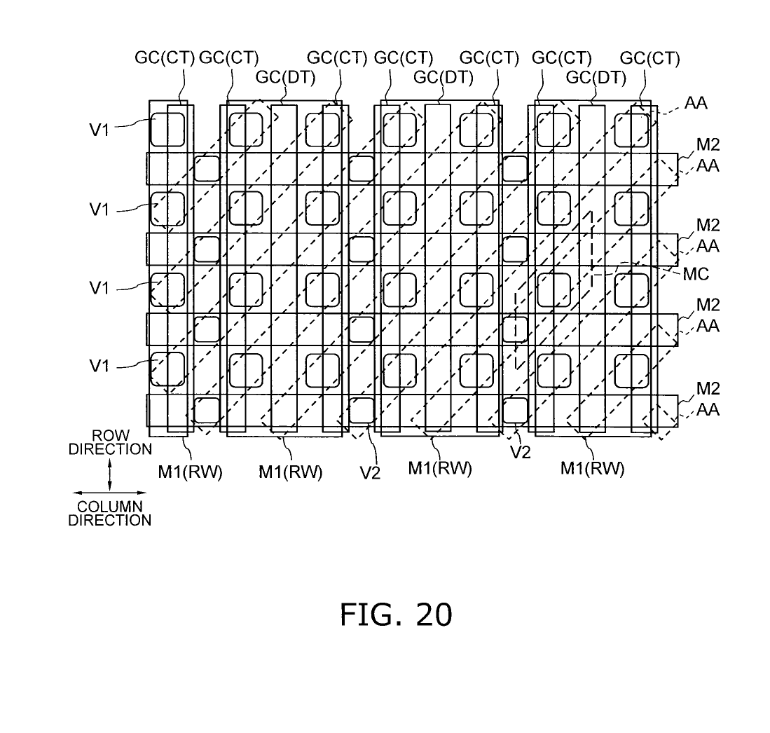

FIG. 20 illustrates a layout of a fourth embodiment of the invention.

In the fourth embodiment, being different from the second embodiment, the active area AA is further oblique with respect to the column direction. Specifically, a distance in the row direction between the second interconnection layer M2 to which the second contact V2 formed on the active area AA is connected and the second interconnection layer M2 to which a neighboring second contact of the second contact on the active area is connected becomes 4 F_{M2}.

The angle of the active area AA with respect to the column direction becomes a tan (4 F_{M2}/6 F_{GC})=a tan (1/1)=approximately 45.0 degrees. Even though the active areas AA having such angles are formed, the active areas AA can be formed in line at predetermined intervals without being divided, and the gate electrodes GC can be formed in line at predetermined intervals.

### Fifth Embodiment

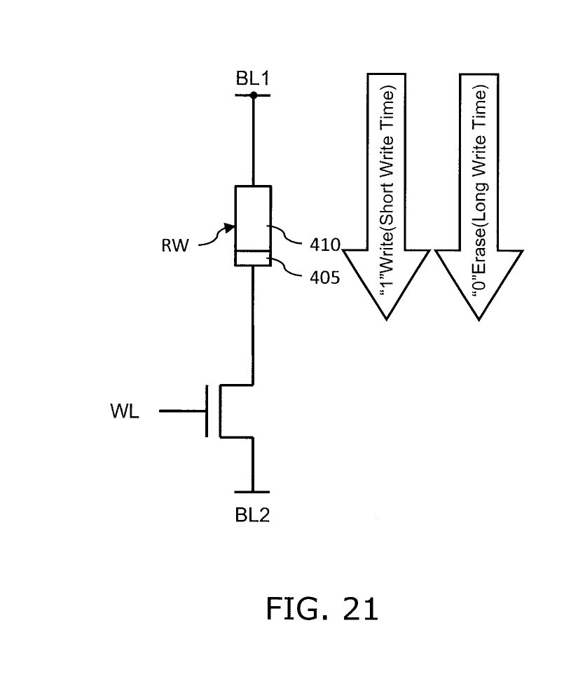

FIG. 21 illustrates a configuration of the variable resistance element RW of a memory device in a fifth embodiment of the invention. Being different from the first embodiment, the memory device uses a phase change memory element as the variable resistance element RW.

The phase change memory element has a phase change layer 410 and a lower electrode layer 405. Otherwise, the phase change memory element may have an upper electrode layer. The phase change layer 410 is formed using GST having germanium, antimony, and tellurium, for example. The GST can change between an amorphous state and a crystalline state by causing a current to flow and generating Joule heat. For example, the GST is high-resistance in the amorphous state and is low-resistance in the crystalline state.

Therefore, data can be stored similarly to the above-described super-lattice variation-type phase change memory element by defining the low-resistance state as data “0” and defining the high-resistance state as data “1”. The low-resistance state may be defined as “1” and the high-resistance state may be defined as “0”.

In order to make the phase change memory element transitional from the low-resistance state to the high-resistance state, a high voltage and a large current are caused to flow in the phase change layer 410 for a short period, and then, the current is suddenly decreased, for example. In other words, the GST configuring the phase change layer 410 is once fused by the large current. Thereafter, the GST can be in the amorphous state in response to rapid cooling caused by a sudden decrease of currents.

Meanwhile, in order to make the phase change memory element transitional from the high-resistance state to the low-resistance state, a high voltage and a large current are caused to flow in the phase change layer 410 for a short period, and then, the current is gradually decreased, for example. In other words, after the phase change layer 410 is fused by the large current, the GST can be in the crystalline state by maintaining a crystallization temperature.

The lower electrode layer 405 can be used for heating the phase change layer 410 as a Joule heat source. Titanium nitride can be exemplified as a specific material, and deposition is performed by a sputtering method or a CVD method.

As an example of the embodiment, the lower electrode layer 405 and the phase change layer 410 described above are used as the variable resistance layer 215 of FIGS. 4A, 4B, 15, 17A to 17C, and 19A to 19C, that is, the orientation layer 105 and the super-lattice layer 110.

Accordingly, the phase change memory element can be used as the variable resistance element RW.

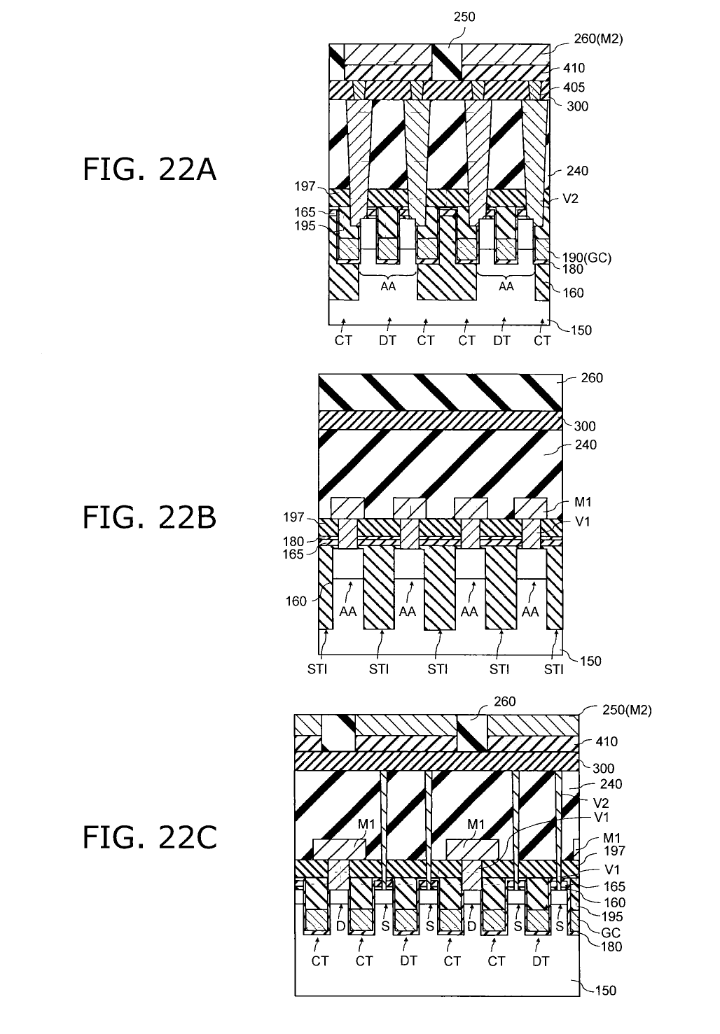

As the variation, the lower electrode layer 405 may be formed in a contact which is provided to be connected to the variable resistance element RW. In addition, the lower electrode layer 405 may be formed as a contact. A description will be given with reference to FIGS. 22A to 22C regarding a case where the variation having the lower electrode layer 405 formed as a contact is applied to the layout of the third embodiment.

FIG. 22A is a cross-sectional view taken along line A-A′ of FIG. 18. FIG. 22B is a cross-sectional view taken along line B-B′ of FIG. 18. FIG. 22C is a cross-sectional view taken along line C-C′ of FIG. 18.

In the case of the variation, as shown in FIG. 22A, the lower electrode layer 405 is formed on the second contact V2. The phase change layer 410 is formed on the lower electrode layer 405.

As a manufacturing method of the variation, for example, the following method is adopted. After forming the second contact V2, a fifth interlayer insulation film 300 is formed. Thereafter, the mask pattern is formed by the lithography method, and etching is performed by the RIE method having the mask pattern as a mask material. In accordance with the etching, a lower electrode hole is formed on the V2.

Subsequently, the lower electrode layer 405 is deposited, and the lower electrode layer on the fifth interlayer insulation film 300 other than the lower electrode hole is removed by the CMP method. Thereafter, the phase change layer 410 is deposited. Then, a general manufacturing method may be adopted.

In this manner, when the lower electrode layer 405 is formed as a contact, a contact portion between the lower electrode layer 405 and the phase change layer 410 is small. Therefore, since a heating portion of the phase change layer 410 is small, a current or a voltage for writing and a current or a voltage for erasing can be decreased, and thus, it is possible to obtain a memory device driven by a low voltage and low current.

### Sixth Embodiment

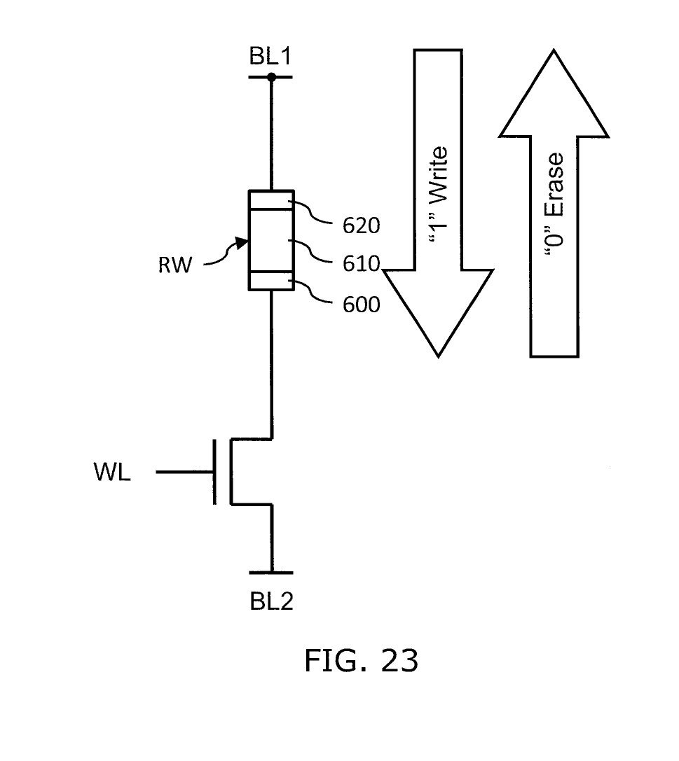

FIG. 23 illustrates a configuration of the variable resistance element RW of the memory device in a sixth embodiment of the invention. Being different from the first embodiment, an ion memory element is used as the variable resistance element RW.

The ion memory element may have an ion source electrode layer 600, an ion diffusion layer 610, and a counter electrode layer 620.

The counter electrode layer 620 is acceptable as long as a conductive material is used, for example, polycrystal silicon or a metallic material. When a metallic material is used, it is favorable to use a metallic element which is unlikely to be diffused in the ion diffusion layer 610.

As a typical example, when silicon is used in the ion diffusion layer 610, titanium nitride, molybdenum, or tantalum is used in the counter electrode layer 620, for example.

The ion diffusion layer 610 is acceptable as long as metal of a second electrode is ionizable, diffusable, and highly resistance. For example, amorphous silicon to which no n-type impurity or p-type impurity is intendedly doped, silicon oxide, silicon nitride, and transitional metallic oxide are used.

It is favorable that the ion source electrode layer 600 is formed using a chemical element nonreactive to silicon. For example, it is preferable to be formed using silver, copper, aluminum, cobalt, nickel, and titanium.

The ion memory element is transitional between the low-resistance state and the high-resistance state according to the following method.

When a voltage is applied to a portion between the ion source electrode layer 600 and the counter electrode layer 620 in a forward direction, metal atoms (metal ion) are conducted from the ion source electrode layer 600 to the ion diffusion layer 610. Accordingly, a filament is formed in the ion diffusion layer. The filament operates as a conductive path between the ion source electrode layer 600 and the counter electrode layer 620, and thus, the ion diffusion layer 610 is in the low-resistance state.

Meanwhile, when a relatively high voltage is applied to the portion between the ion source electrode layer 600 and the counter electrode layer 620 in a reverse direction, metal ions in the filament are subjected to ionic conduction conversely to an ion source electrode, thereby disconnecting the conductive path operated by the filament. Accordingly, the ion diffusion layer 610 is in the high-resistance state.

Therefore, data can be stored similar to the above-described super-lattice variation-type phase change memory element by defining the low-resistance state as data “0” and defining the high-resistance state as data “1”.

As an example of the embodiment, the ion source electrode layer 600, the ion diffusion layer 610, and the counter electrode layer 620 described above are used as the variable resistance layer 215 of FIGS. 4A, 4B, 15, 17A to 17C, and 19A to 19C, that is, the orientation layer 105 and the super-lattice layer 110.

As the variation, the ion source electrode layer 600 or the counter electrode layer 620 may be formed in a contact which is provided to be connected to the variable resistance element RW, or may be formed as a lower layer of the interconnection layer which is provided to be connected to an upper layer of the variable resistance element RW.

In the descriptions for several embodiments of the invention, the embodiments are proposed as examples and are not intended to limit the scope of the invention. The newly proposed embodiments can be executed in other various forms and can be subjected to various types of omission, replacement, and changes without departing from the spirit of the invention. The embodiments and the variations thereof are included within the scope and the spirit of the invention and are included within a scope which is equivalent to the invention disclosed in Claims.

What is claimed is:

1. A memory device comprising:
a first gate electrode on a substrate, the first gate electrode extending in a first direction, the first direction being parallel to the substrate;
a second gate electrode on the substrate, the second gate electrode extending in the first direction;
a third gate electrode on the substrate, the third gate electrode extending in the first direction,
the first gate electrode, the second gate electrode and the third gate electrode being provided in order thereof apart from each other in a second direction, the second direction being parallel to the substrate and crossing the first direction;
a first active area on the substrate, the first active area crossing the first gate electrode, the second gate electrode and the third gate electrode, the first active area extending in the second direction;
a second active area on the substrate, the second active area being provided apart from the first active area in the first direction, the second active area crossing the first gate electrode, the second gate electrode and the third gate electrode, the second active area being electrically insulated from the first active area, the second active area extending in the second direction;
a first contact electrically connected to the first active area between the first gate electrode and the second gate electrode;
a second contact electrically connected to the first active area between the second gate electrode and the third gate electrode;
a third contact electrically connected to the second active area between the first gate electrode and the second gate electrode;
a fourth contact electrically connected to the second active area between the second gate electrode and the third gate electrode;
a variable resistance layer extending in the first direction;
a first interconnection layer extending in the first direction,
the variable resistance layer having a lower surface and a upper surface, the lower surface being connected to the first contact and the third contact, the upper surface being connected to the first interconnection layer;
a second interconnection layer above the first interconnection layer, the second interconnection layer being electrically connected to the second contact, the second interconnection layer extending in the second direction; and
a third interconnection layer above the first interconnection layer, the third interconnection layer being electrically connected to the fourth contact, the third interconnection layer extending in the second direction.

2. The memory device according to claim 1, wherein
the first gate electrode, the second gate electrode and third gate electrode have a pitch same as each other.

3. The memory device according to claim 1, wherein
the second gate electrode is applied a voltage lower than a voltage applied to the first gate electrode and the third gate electrode when a data is read out.

4. The memory device according to claim 3, wherein
the voltage applied to the second gate electrode is equal to 0 V for a voltage of the substrate.

5. A memory device comprising:
a first gate electrode on a substrate, the first gate electrode extending in a first direction, the first direction being parallel to the substrate;
a second gate electrode on the substrate, the second gate electrode extending in the first direction;
a third gate electrode on the substrate, the third gate electrode extending in the first direction;
a fourth gate electrode on the substrate, a fourth gate electrode extending in the first direction;
a fifth gate electrode on the substrate, the fifth gate electrode extending in the first direction,
the first gate electrode, the second gate electrode, the third gate electrode, the fourth gate electrode and the fifth gate electrode being provided in order thereof apart from each other in a second direction, the second direction being parallel to the substrate, the second direction crossing the first direction;
a first active area on the substrate, the first active area crossing the first gate electrode, the second gate electrode, the third gate electrode, the fourth gate electrode and the fifth gate electrode;
a second active area on the substrate, the second active area being provided apart from the first active area in the first direction, the second active area crossing the first gate electrode, the second gate electrode, the third gate electrode, the fourth gate electrode and the fifth gate electrode, the second active area being electrically insulated from the first active area;
a first contact electrically connected to the first active area between the first gate electrode and the second gate electrode;
a second contact electrically connected to the first active area between the second gate electrode and the third gate electrode;
a third contact electrically connected to the first active area between the third gate electrode and the fourth gate electrode;
a fourth contact electrically connected to the first active area between the fourth gate electrode and the fifth gate electrode;
a fifth contact electrically connected to the second active area between the first gate electrode and the second gate electrode;
a sixth contact electrically connected to the second active area between the second gate electrode and the third gate electrode;
a seventh contact electrically connected to the second active area between the third gate electrode and the fourth gate electrode;
an eighth contact electrically connected to the second active area between the fourth gate electrode and the fifth gate electrode;
a variable resistance layer extending in the first direction;
a first interconnection layer extending in the first direction,
the variable resistance layer having a lower surface and an upper surface, being electrically connected to the second contact, the third contact, the sixth contact and the seventh contact on the lower surface, being electrically connected to the first interconnection on the upper surface;
a second interconnection layer electrically connected to the first contact, the second interconnection layer extending in the second direction; and
a third interconnection layer provided apart from the second interconnection layer in the first direction, the third interconnection layer being electrically connected to the fifth contact, the third interconnection layer extending in the second direction.

6. The memory device according to claim 5, wherein
the first gate electrode, the second gate electrode, the third gate electrode, the fourth gate electrode and fifth gate electrode have a pitch same as each other.

7. The memory device according to claim 5, wherein
the third gate electrode is applied a voltage lower than a voltage applied to the second gate electrode and the fourth gate electrode when a data is read out.

8. The memory device according to claim 7, wherein
the voltage applied to the third gate electrode is equal to 0 V for a voltage of the substrate.

9. The memory device according to claim 5, wherein
the first active area and the second active area extend in the second direction,
the second interconnection layer is provided above the first interconnection layer and connected to the fourth contact, and
the third interconnection layer is provided above the first interconnection layer and connected to the eighth contact.

10. The memory device according to claim 5, wherein
the second contact is provided on the first active area and the second gate electrode and
the third contact is provided on the first active area and the fourth gate electrode.

11. The memory device according to claim 5, further comprising
a fourth interconnection layer electrically connected to the eighth contact, the fourth interconnection layer being provided apart from the third interconnection layer in the first direction, the fourth interconnection layer extending in the second direction,
the first active area and the second active area extending in a third direction crossing the first direction and the second direction,
the third interconnection layer is electrically connected to the fourth contact.

12. The memory device according to claim 5, wherein
the variable resistance element includes a super-lattice layer having a layer that reversibly changes positions of atoms by supplying an electrical energy to the layer.

13. The memory device according to claim 12, wherein
the variable resistance element includes an orientation layer that improves orientation of the super-lattice layer.

14. The memory device according to claim 5, wherein
the variable resistance element includes a phase change layer that changes a resistance value by changing a crystalline structure with Joule heat.

15. The memory device according to claim 12, wherein
the variable resistance element includes at least one of Germanium, Antimony and Tellurium.

16. The memory device according to claim 5, wherein
the variable resistance element includes an ion memory element that changes a resistance value with a direction of a voltage.

17. A memory device comprising a plurality of pairs of memory cells,
each of the pairs including:
a first transistor on an active area, the first transistor having a first source region, a first drain region and a first gate electrode on a substrate, the first gate electrode between the first source region and the first drain region;
a second transistor on the active area, the second transistor being provided apart from the first transistor, the second transistor having a second source region, a second drain region and a second gate region on the substrate, the second gate electrode between the second source region and the second drain region;
a third transistor between the first transistor and the second transistor, the third transistor having a third gate electrode;
a first via contact electrically connected to the first source region with one end;
a second via contact electrically connected to the second source region with one end;
a variable resistance layer above the third gate electrode, the variable resistance layer being electrically connected to each of other ends of the first via contact and the second via contact;
a first interconnection layer electrically connected to an upper surface of the variable resistance layer;
a third via contact electrically connected to the first drain region the one end;
a fourth via contact electrically connected to the second drain region with one end; and
a second interconnection layer electrically connected to each of other ends of the third via contact and the fourth via contact.

18. The memory device according to claim 17, wherein
the second interconnection layer is provided above the first interconnection layer.

19. The memory device according to claim 17, wherein
the second interconnection layer is provided below the first interconnection layer.

20. The memory device according to claim 17, wherein
the plurality of pairs of the memory cells are arrayed in a lattice shape in a first direction parallel to a surface of the substrate and in a second direction that crosses the first direction.
